(19) United States
(12) Patent Application Publication
(10) Pub. No.: US 2024/0291704 A1
(43) Pub. Date: Aug. 29, 2024

(54) METHOD, SYSTEM AND COMPUTER-READABLE STORAGE MEDIUM FOR INTEGER SIGNAL FREQUENCY SPECTRUM SAMPLING AND INTEGER SIGNAL RECOVERY

(71) Applicant: CHUNGHWA TELECOM CO., LTD., Taoyuan City (TW)

(72) Inventor: Kuo-Wei CHANG, Taoyuan City (TW)

(21) Appl. No.: 18/212,245

(22) Filed: Jun. 21, 2023

(30) Foreign Application Priority Data
Feb. 24, 2023 (TW) 112107094

(51) Int. Cl. H04L 27/26

(52) U.S. Cl. CPC H04L 27/2655

(57) ABSTRACT

The present disclosure provides a technology for sampling frequency spectrums of integer signals and recovering integer signals. For a known signal sequence consisting of integers, it is sufficient to select proper samples from a Fourier transform frequency spectrum of the signal sequence and transmit the selected samples, thereby achieving the effect of signal compression. Further, the receiver apparatus can recover the integer signal sequence without any distortion by the method disclosed in the present disclosure.

### BACKGROUND

### 1. Technical Field

The present disclosure relates to a lossless compression solution applicable to signal transmission. In particular, the present disclosure relates to a technology for sampling frequency spectrums of integer signals and recovering integer signals.

### 2. Description of Related Art

In existing transmission compression methods, information in certain frequency bands to which the human eyes or ears are insensitive is usually removed. Although the recovered signal is different from the original signal, the human user can hardly notice the difference. Such compression is called lossy compression.

On the other hand, compression can also be done by means of a large dictionary. For example, an N×M matrix (N>>M, i.e., N is much larger than M) is constructed in advance, and then the concept of compressed sensing is used to transform the signal from M points to N dimensions, which appears to increase the dimensions, but in fact, only K points in these N dimensions have values (K<<M, i.e., K is much smaller than M). Thus, there is a compression effect, and it is lossless compression.

In addition, recently there is another technique that differs from the two aforementioned methods. Firstly, this method is lossless compression, i.e., the recovered signal is exactly the same as the original signal. Secondly, this technique does not need to build a large dictionary, so it saves the storage spaces of the transmitter apparatus and the receiver apparatus. However, this technique requires sampling about 33% of the length of the original signal. Therefore, its performance needs to be improved.

### SUMMARY

In order to solve the above problems, the present disclosure provides a method for integer signal frequency spectrum sampling and integer signal recovery, including: performing a Fast Fourier Transform on an original integer signal to obtain a frequency spectrum of the original integer signal, wherein the original integer signal is a sequence formed by N integers greater than or equal to 0, and N is a power of 2; sampling the frequency spectrum to obtain a plurality of samples; generating an original sample sequence formed by the plurality of samples; transmitting the original sample sequence; and recovering the original integer signal from the original sample sequence.

The present disclosure further provides a computer-readable storage medium, storing instructions therein, when executed by a computing device or an electronic device, cause the computing device or the electronic device to implement the aforementioned method for integer signal frequency spectrum sampling and integer signal recovery.

The present disclosure further provides a system for integer signal frequency spectrum sampling and integer signal recovery. The system includes a transmitter apparatus and a receiver apparatus. The transmitter apparatus includes a first processor and a transmitter module. The first processor is configured for performing a Fast Fourier Transform on an original integer signal to obtain a frequency spectrum of the original integer signal. The original integer signal is a sequence formed by N integers greater than or equal to 0. N is a power of 2. The first processor is further configured for sampling the frequency spectrum to obtain a plurality of samples, generating an original sample sequence formed by the plurality of samples. The transmitter module is configured for transmitting the original sample sequence. The receiver apparatus includes a second processor and a receiver module. The transmitter apparatus and the receiver apparatus are communicatively or electrically connected to each other. The receiver module is configured for receiving the original sample sequence. The second processor is configured for recovering the original integer signal from the original sample sequence so that the receiver apparatus stores the original sample sequence and the original integer signal.

In a process of transmitting an integer signal, the present disclosure can transmit only a part of the frequency spectrum of the integer signal instead of the entire frequency spectrum to achieve the benefit of saving transmission bandwidth.

### BRIEF DESCRIPTION OF THE DRAWINGS

The present disclosure can be more fully understood by reading the following descriptions of the embodiments, with reference made to the accompanying drawings.

FIG. 1 is a schematic flowchart of a method for integer signal frequency spectrum sampling and integer signal recovery according to an embodiment of the present disclosure.

FIG. 2 is a schematic flowchart of a method for integer signal recovery according to an embodiment of the present disclosure.

FIGS. 3 to 5 are schematic block diagrams of a transmitter apparatus and a receiver apparatus according to an embodiment of the present disclosure.

### DETAILED DESCRIPTION OF THE EMBODIMENTS

The following embodiments are used for illustrating the present disclosure. A person skilled in the art can easily conceive the other advantages and effects of the present disclosure, based on the disclosure of the specification. The present disclosure can also be implemented or applied as described in different embodiments. It is possible to modify or alter the following embodiments for carrying out this disclosure without contravening its spirit and scope, for various aspects and applications.

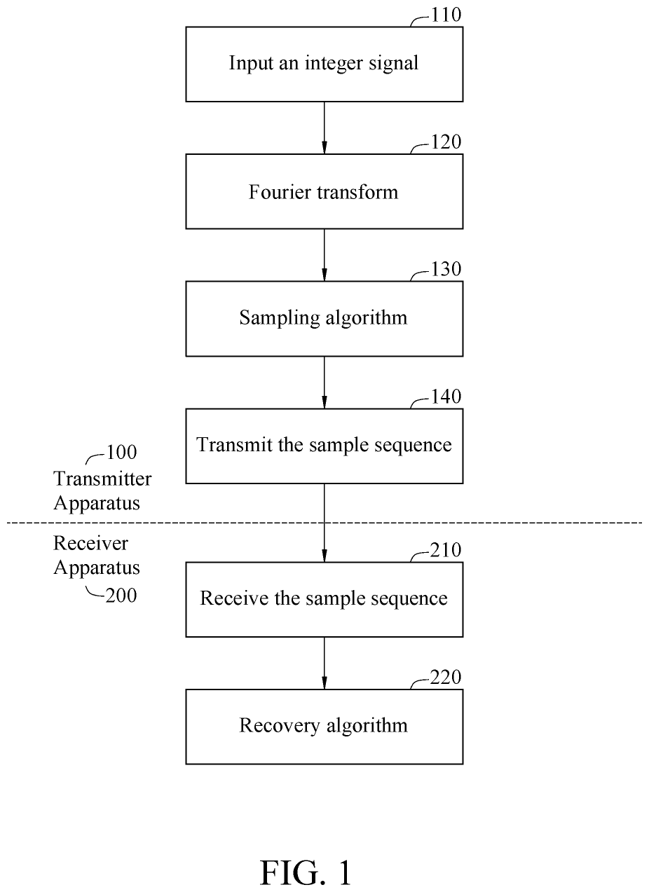

FIG. 1 is a schematic flowchart of a method for integer signal frequency spectrum sampling and integer signal recovery according to an embodiment of the present disclosure. The method for integer signal frequency spectrum sampling and integer signal recovery may be divided into a method for integer signal frequency spectrum sampling and a method for integer signal recovery.

Firstly, the transmitter apparatus 100 executes the method for integer signal frequency spectrum sampling corresponding to steps 110 to 140 to transform an input integer signal into a discrete Fourier transform, to sample the discrete Fourier transform to obtain a sample sequence, and then to transmit the sample sequence to the receiver apparatus 200.

Next, the receiver apparatus 200 executes the method for integer signal recovery corresponding to steps 210-220 to receive the sample sequence, and then to recover the original integer signal from the sample sequence.

In an embodiment, the transmitter apparatus 100 and the receiver apparatus 200 may be computing devices or electronic devices capable of processing, computing, transmitting, and receiving data. The transmitter apparatus 100 and the receiver apparatus 200 are communicatively or electrically connected to each other. The flow shown in FIG. 1 is described below.

Firstly, in step 110, an integer signal is input into the transmitter apparatus 100. The integer signal is an N-point integer sequence, i.e., a sequence of N integers x(0), x(1), . . . , x(N−1), and each integer in the sequence is greater than or equal to 0. N is a power of 2, e.g., 32, 64, 128 or 256, etc.

Next, in step 120, Fast Fourier Transform (FFT) is used to obtain the Discrete Fourier Transform (DFT) X(0), X(1), . . . , X(N−1) of the integer signal. In general, X(0), X(1), . . . , X(N−1) are all complex numbers. In addition, the discrete Fourier transform of the integer signal can also be called the frequency spectrum of the integer signal.

Next, in step 130, the frequency spectrum is sampled to obtain a sample sequence of the frequency spectrum. In detail, if the value of N is smaller, e.g., less than or equal to M (M is also a power of 2), then the complex number in the frequency spectrum with the index number 0 and all of the complex numbers in the frequency spectrum with index numbers that are greater than 0 and less than N and can divide N may be selected as the samples in the sample sequence.

In an embodiment, if N=32, then the complex numbers in the frequency spectrum with the index numbers 0, 1, 2, 4, 8, 16 are selected as the samples. In other words, the sample sequence consists of the six complex numbers X(0), X(1), X(2), X(4), X(8), X(16) in the frequency spectrum. These samples are sorted in the sample sequence according to the index numbers of these samples in the frequency spectrum. The resultant order of the sorting is from the sample with the smallest index number to the sample with the largest index number.

In the following, an actual 32-point binary signal is taken as an example to illustrate steps 110, 120 and 130. The integer signal x(n) input into the transmitter apparatus 100 is:
1, 0, 0, 1, 0, 0, 1, 0, 1, 1, 0, 1, 0, 1, 1, 1, 1, 0, 0, 1, 0, 0, 0, 0, 1, 1, 0, 0, 0, 0, 0, 0
and its frequency spectrum X(k) obtained through FFT is:
13.0000+0i, −2.9090−2.8887i, −0.1585+1.1481i, −0.9622−2.2726i, 3.2929−0.1213i, 1.5367−0.5870i, −2.2304+2.7716i, 0.0702−2.0114i, 2.0000+1.0000i, 1.0122+0.6017i, 2.2304+2.7716i, 1.0764+0.4954i, 4.7071−4.1213i, −1.6510−1.1902i, 0.1585+1.1481i, 1.8266−0.2756i, −1.0000+0i, 1.8266+0.2756i, 0.1585−1.1481i, −1.6510+1.1902i, 4.7071+4.1213i, 1.0764−0.4954i, 2.2304−2.7716i, 1.0122−0.6017i, 2.0000−1.0000i, 0.0702+2.0114i, −2.2304−2.7716i, 1.5367+0.5870i, 3.2929+0.1213i, −0.9622+2.2726i, −0.1585−1.1481i, −2.9090+2.8887i

Traditionally, all of X(k), k=0˜31, are required to recover the integer signal x(n). However, if the aforementioned method of the present disclosure is used, only X(k), k=0, 1, 2, 4, 8, 16, namely, X(0)=13, X(1)=−2.9090−2.8887i, X(2)=−0.1585+1.1481i, X(4)=3.2929−0.1213i, X(8)=2.0000+1.0000i, X(16)=−1.0000+0i, are needed for the recovery of the integer signal x(n).

On the other hand, if the value of N is larger, e.g., greater than M, then the integer 0, the integers that are greater than 0 and less than M and can divide M, and each aforementioned integer (including 0) plus M*j (j is each integer from 1 to d−1 and d=N/M) may be selected as the index numbers of the samples of the sample sequence in the frequency spectrum.

In another embodiment, if N=128 and M=64, then 0, 1, 2, 4, 8, 16, 32, 64, 65, 66, 68, 72, 80, 96 may be selected as the index numbers of the samples, wherein 1, 2, 4, 8, 16, 32 are all the integers that are greater than 0 and less than M and can divide M, and the index numbers 64, 65, 66, 68, 72, 80, 96 are obtained by adding M to each of the index numbers 0, 1, 2, 4, 8, 16, 32. Therefore, the sample sequence is formed by the 14 complex numbers X(0), X(1), X(2), X(4), X(8), X(16), X(32), X(64), X(65), X(66), X(68), X(72), X(80), X(96) in the frequency spectrum.

In another embodiment, if N=256 and M=64, in addition to the aforementioned 14 index numbers of the samples corresponding to the value 128 of N, 128 (64*2) and 192 (64*3) may be respectively added to each of the index numbers 0, 1, 2, 4, 8, 16, 32 to generate another 14 index numbers, making a total of 28 index numbers. In this case, the sample sequence is formed by the 28 complex numbers corresponding to the 28 index numbers in the frequency spectrum.

In the above two embodiments, the amount of data of the sample sequence obtained by sampling is much smaller than that of the complete frequency spectrum before the sampling, such that the data compression effect can be achieved and the overall performance can be improved.

Next, in step 140, the transmitter apparatus 100 transmits the sample sequence to the receiver apparatus 200 via wired or wireless communication.

In step 210, the receiver apparatus 200 receives the sample sequence.

Next, in step 220, the receiver apparatus 200 executes a recovery method, so as to obtain the original integer signal, namely, the integer signal input to the transmitter apparatus 100 in step 110, according to the sample sequence.

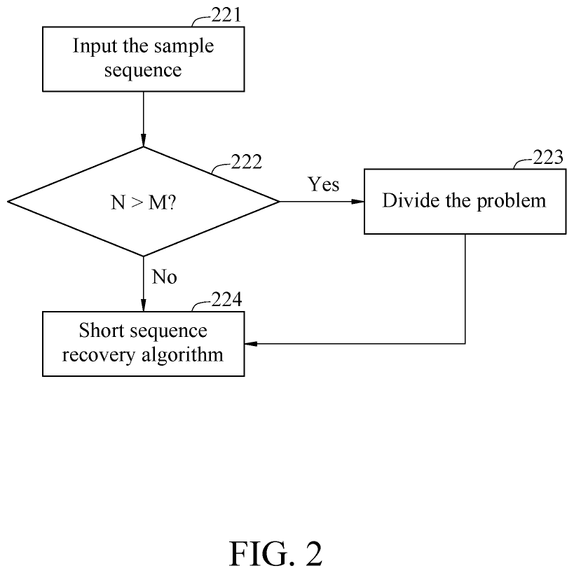

The flow of the recovery method of step 220 is shown in FIG. 2.

Firstly, in step 221, the sample sequence is input into the recovery method.

Next, in step 222, it is determined whether the length N of the original integer signal is greater than M. If N is less than or equal to M, the flow proceeds to step 224. Otherwise, the flow proceeds to step 223.

In step 224, a short sequence recovery method is executed to recover the original integer signal x(0), x(1), . . . , x(N−1) from the sample sequence, so as to achieve the purpose of data transmission. In an embodiment, the short sequence recovery method in step 224 may use an algorithm, for example, but is not limited to, exhaustive search, branch and bound, or any other technique that can solve a mixed integer linear programming problem.

In an embodiment, if N=32, since N=32 is less than M=64, after the receiver apparatus 200 receives the sample sequence formed by the six complex numbers X(0), X(1), X(2), X(4), X(8) and X(16) in step 221, the flow proceeds to step 224 to execute the short sequence recovery method, in order to recover the integer signal x(0), x(1), . . . , x(31) from X(0), X(1), X(2), X(4), X(8) and X(16).

On the other hand, in step 223, if the length of the sample sequence is L, i.e., the sample sequence includes L complex number samples, then d sample sequences of length L/d are generated based on the sample sequence of length L to divide the original N-point mixed integer linear programming problem into d M-point mixed integer linear programming problem, wherein d=N/M. Next, the short sequence recovery method is used in step 224 to recover d M-point integer signals respectively from the d sample sequences of length L/d, and then the d M-point integer signals are combined into the original N-point integer signal.

In another embodiment, if N=128, since N=128 is greater than M=64 and d=128/64=2, after the receiver apparatus 200 receives the sample sequence formed by the L=14 complex numbers in step 221, the flow proceeds to step 223 to divide the 128-point problem into two 64-point problems, and then the flow proceeds to step 224 to use the short sequence recovery method to recover two 64-point integer signals and then combine the two 64-point integer signals into the original 128-point integer signal.

In view of the above, if d=2, the details of the dividing of the problem in step 223 are described in the following.

Firstly, two sample sequences Ev(k) and Od(k) of length L/2 may be obtained based on the original sample sequence of length L and the following equations.

$$Ev ( k ) = [ X ( k ) + X ( k + M ) ] / 2$$

$$Od ( k ) = [ X ( k ) - X ( k + M ) ] / 2 / W$$

In the above equations, k belongs to a set including the integer 0 and all the integers that are greater than 0 and are less than M and can divide M. For example, if M=64, then k=0, 1, 2, 4, 8, 16, 32. In addition, W=exp(−2πi/N).

According to the characteristics of Fourier transform, Ev(k), k=0, 1, 2, 4, 8, 16, 32 is equivalent to a sample sequence that is obtained by performing a 64-point Fourier transform on a sequence formed by the 64 points with even index numbers (x(2n), n=0, 1, 2, . . . , 63) in the original integer signal, and then sampling at the index numbers k=0, 1, 2, 4, 8, 16, 32. In other words, it is a 64-point mixed integer linear programming problem.

Similarly, Od(k), k=0, 1, 2, 4, 8, 16, 32 is equivalent to a sample sequence that is obtained by sampling at the index numbers k=0, 1, 2, 4, 8, 16, 32 after performing a 64-point Fourier transform on a sequence formed by the 64 points with odd index numbers (x(2n+1), n=0, 1, 2, . . . , 63) in the original integer signal. In other words, it is another separate 64-point mixed integer linear programming problem.

The original 128-point integer signal can be obtained by interleaving the integers of the two 64-point integer signals that are recovered respectively according to Ev(k) and Od(k). Similar processes of the dividing of the problem and the combining of the integer signals can be deduced by a person skilled in the art when M is another power of two.

The above embodiment and process transform a 128-point problem into two 64-point problems. If exhaustive search is used in the recovery in step 224, there are 2128 combinations in the exhaustive search for the original 128-point problem, while there are only 265=2*264 combinations in the exhaustive search for the two 64-point problems after the dividing, which greatly reduces the complexity of recovery and improves the overall performance.

Furthermore, when d is equal to 2 or another value, common knowledge in the art can be used to process the dividing of the mixed integer linear programming problem in step 223. For example, a person skilled in the art can refer to “On Hardware Implementation of Radix 3 and Radix 5 FFT Kernels for LTE Systems” by Johan Lofgren and Peter Nilsson in 2011 NORCHIP, pp. 1-4, IEEE, 2011. The present disclosure is not limited thereto.

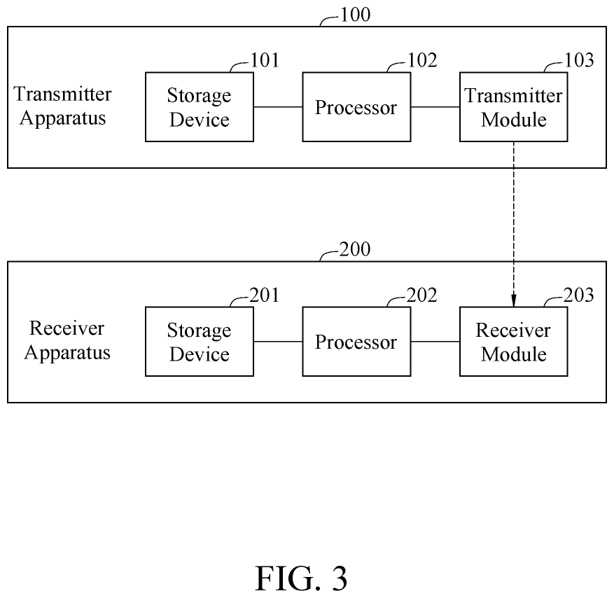

FIGS. 3 to 5 are schematic block diagrams of a transmitter apparatus 100 and a receiver apparatus 200 according to an embodiment of the present disclosure.

In this embodiment, as shown in FIG. 3, the transmitter apparatus 100 includes a storage device 101, a processor 102, and a transmitter module 103, wherein the processor 102 is communicatively connected to the storage device 101 and the transmitter module 103. The receiver apparatus 200 includes a storage device 201, a processor 202, and a receiver module 203, wherein the processor 202 is communicatively connected to the storage device 201 and the receiver module 203.

In an embodiment, each of the storage device 101 and the storage device 201 may be a memory, a hard disk, or other hardware device capable of storing data, while each of the transmitter module 103 and the receiver module 203 may be a hardware module, a software module, or a firmware module.

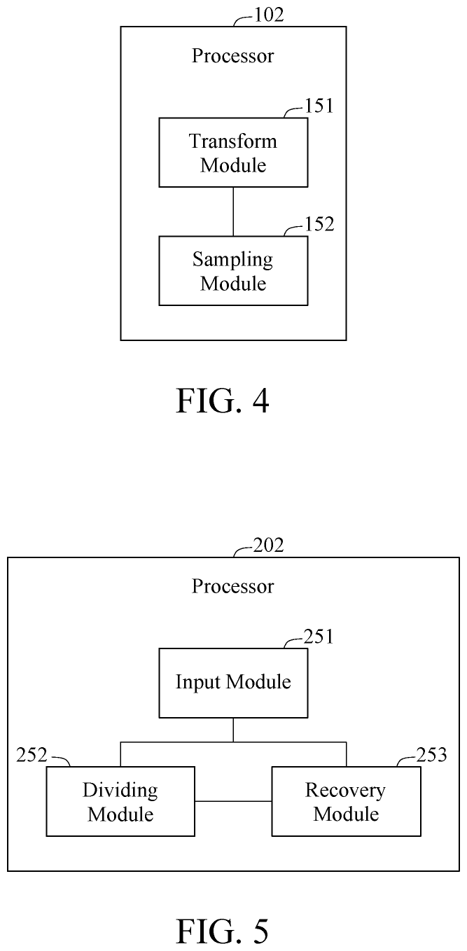

As shown in FIG. 4, the processor 102 of the transmitter apparatus 100 includes a transform module 151 and a sampling module 152 communicatively connected to each other. Each of the transform module 151 and the sampling modules 152 may be a hardware module, a software module, or a firmware module.

As shown in FIG. 5, the processor 202 of the receiver apparatus 200 includes an input module 251, a dividing module 252 and a recovery module 253 communicatively connected to each other. Each of the input module 251, the dividing module 252 and the recovery module 253 may be a hardware module, a software module, or a firmware module.

The transmitter apparatus 100 and the receiver apparatus 200 in this embodiment may be configured to execute the aforementioned method for integer signal frequency spectrum sampling and the method for integer signal recovery.

Specifically, please refer to FIG. 1 and FIG. 3, the storage device 101 of the transmitter apparatus 100 may store the integer signal that is input into the transmitter apparatus 100 in step 110. The processor 102 may be configured to execute step 120 and step 130, wherein the transform module 151 is configured to execute step 120 and the sampling module 152 is configured to execute step 130. In steps 140 and 210, the transmitter module 103 of the transmitter apparatus 100 may transmit the sample sequence to the receiver module 203 of the receiver apparatus 200 through wired or wireless communication.

In addition, the storage device 201 of the receiver apparatus 200 may store the sample sequence received by the receiver module 203 in step 210. The processor 202 is configured to execute step 220, wherein the input module 251 is configured to receive the sample sequence in step 221 and is further configured to perform the determination in step 222. Moreover, the dividing module 252 is configured to execute step 223. The recovery module 253 is configured to execute step 224 and is further configured to store the recovered original integer signal into the storage device 201.

In another embodiment, the present disclosure provides a computer-readable storage medium including at least one memory, floppy disk, hard disk and/or optical disk. The computer-readable storage medium stores instructions that can be read by the transmitter apparatus 100 and the receiver apparatus 200, or by any other computing device or electronic device, to execute the aforementioned method for integer signal frequency spectrum sampling and integer signal recovery.

The present disclosure provides a lossless compression technique applicable to signal transmission. In the process of frequency spectrum sampling and recovery of an integer signal, the number of samples varies according to the length of the integer signal sequence. And in the process of recovering the integer signal, different strategies are used depending on the length of the integer signal sequence.

In addition, when the integer signal sequence is longer, it is divided into several short signal sequences for individual recovery, while when the integer signal sequence is shorter, the original integer signal is calculated directly.

In summary, when transmitting an integer signal, the present disclosure transmits only a part of the integer signal frequency spectrum instead of the entire frequency spectrum, thereby compressing the integer signal to save the transmission bandwidth between the transmitter apparatus and the receiver apparatus, and to improve the transmission efficiency between the transmitter apparatus and the receiver apparatus. Moreover, the receiver apparatus can recover the integer signal without any distortion through the recovery method disclosed by the present disclosure.

Accordingly, the present disclosure can use a sampling rate of about 11% to recover an integer signal sequence formed by 64 0/1 bit values in 0.03 seconds, which is a significant improvement over the conventional lossless compression technique that requires a sampling rate of 33%. Therefore, the present disclosure can significantly reduce the hardware resources such as processors and storage devices (e.g., the aforementioned modules) required for compression and recovery, maintain the advantage of lossless compression without the need for a big dictionary, and improve the overall performance.

While some of the embodiments of the present disclosure have been described in detail above, it is, however, possible for those of ordinary skill in the art to make various modifications and changes to the particular embodiments shown without substantially departing from the teaching and advantages of the present disclosure. Such modifications and changes are encompassed in the spirit and scope of the present disclosure as set forth in the appended claims.

What is claimed is:

1. A method for integer signal frequency spectrum sampling and integer signal recovery, the method comprising:
performing a Fast Fourier Transform on an original integer signal to obtain a frequency spectrum of the original integer signal, wherein the original integer signal is a sequence formed by N integers greater than or equal to 0, and N is a power of 2;
sampling the frequency spectrum to obtain a plurality of samples;
generating an original sample sequence formed by the plurality of samples;
transmitting the original sample sequence; and
recovering the original integer signal from the original sample sequence.

2. The method according to claim 1, wherein the samples are sorted in the original sample sequence according to index numbers of the samples in the frequency spectrum.

3. The method according to claim 1, wherein index numbers of the samples in the frequency spectrum comprise 0 and/or all integers that are greater than 0 and less than N and can divide N.

4. The method according to claim 1, further comprising:
executing a short sequence recovery method on the original sample sequence to recover the original integer signal.

5. The method according to claim 1, wherein index numbers of the samples in the frequency spectrum comprise d sets of index numbers, d=N/M, M is a power of 2 less than N, wherein the 0-th set of the d sets of index numbers comprises 0 and/or all integers that are greater than 0 and less than M and can divide M, and wherein the j-th set of the d sets of index numbers comprises integers that are obtained by adding M*j to each of the index numbers in the 0-th set of index numbers, j is an integer and 1<=j<=d−1.

6. The method according to claim 5, further comprising:
generating d short sample sequences according to the original sample sequence, wherein a number of samples in each of the short sample sequences is 1/d of a number of samples in the original sample sequence;
using a short sequence recovery method to recover d short integer signals respectively from the short sample sequences, wherein each of the short integer signals is a sequence formed by M integers in the original integer signal; and
combining the short integer signals into the original integer signal.

7. The method according to claim 6, wherein if d is equal to 2, each of the samples in each of the short sample sequences is generated by a calculation based on two of the samples in the original sample sequence, with a difference of M between the index numbers of the two samples in the original sample sequence.

8. The method according to claim 6, further comprising:
interleaving the integers of the short integer signals to combine the short integer signals into the original integer signal.

9. A computer-readable storage medium, storing instructions therein, when executed by a computing device or an electronic device, cause the computing device or the electronic device to implement the method for integer signal frequency spectrum sampling and integer signal recovery according to claim 1.

10. A system for integer signal frequency spectrum sampling and integer signal recovery, the system comprising:
a transmitter apparatus, comprising a first processor and a transmitter module, wherein the first processor is configured for performing a Fast Fourier Transform on an original integer signal to obtain a frequency spectrum of the original integer signal, the original integer signal is a sequence formed by N integers greater than or equal to 0, N is a power of 2, the first processor is further configured for sampling the frequency spectrum to obtain a plurality of samples, generating an original sample sequence formed by the plurality of samples, and the transmitter module is configured for transmitting the original sample sequence; and
a receiver apparatus, comprising a second processor and a receiver module, wherein the transmitter apparatus s and the receiver apparatus are communicatively or electrically connected to each other, the receiver module is configured for receiving the original sample sequence, the second processor is configured for recovering the original integer signal from the original sample sequence so that the receiver apparatus stores the original sample sequence and the original integer signal.

11. The system according to claim 10, wherein the samples are sorted in the original sample sequence according to index numbers of the samples in the frequency spectrum.

12. The system according to claim 10, wherein index numbers of the samples in the frequency spectrum comprise 0 and/or all integers that are greater than 0 and less than N and can divide N.

13. The system according to claim 10, wherein the receiver apparatus is further configured for:
executing a short sequence recovery method on the original sample sequence to recover the original integer signal.

14. The system according to claim 10, wherein index numbers of the samples in the frequency spectrum comprise d sets of index numbers, d=N/M, M is a power of 2 less than N, wherein the 0-th set of the d sets of index numbers comprises 0 and/or all integers that are greater than 0 and less than M and can divide M, and wherein the j-th set of the d sets of index numbers comprises integers that are obtained by adding M*j to each of the index numbers in the 0-th set of index numbers, j is an integer and 1<=j<=d−1.

15. The system according to claim 14, wherein the receiver apparatus is further configured for:
generating d short sample sequences according to the original sample sequence, wherein a number of samples in each of the short sample sequences is 1/d of a number of samples in the original sample sequence;
using a short sequence recovery method to recover d short integer signals respectively from the short sample sequences, wherein each of the short integer signals is a sequence formed by M integers in the original integer signal; and
combining the short integer signals into the original integer signal.

16. The system according to claim 15, wherein if d is equal to 2, each of the samples in each of the short sample sequences is generated by a calculation based on two of the samples in the original sample sequence, with a difference of M between the index numbers of the two samples in the original sample sequence.

17. The system according to claim 15, wherein the receiver apparatus is further configured for:
interleaving the integers of the short integer signals to combine the short integer signals into the original integer signal.
